(19) United States
(12) Patent Application Publication
(10) Pub. No.: US 2025/0118715 A1
(43) Pub. Date: Apr. 10, 2025

(54) MICROELECTROMECHANICAL SYSTEMS (MEMS) AND RELATED PACKAGES

(71) Applicant: Analog Devices, Inc., Wilmington, MA (US)

(72) Inventors: Xin Zhang, Acton, MA (US); Jianglong Zhang, McLean, VA (US); Li Chen, Belmont, MA (US); John C. Cowles, Beaverton, OR (US); Michael Judy, Ipswich, MA (US); Shafi Saiyed, Lynnfield, MA (US)

(73) Assignee: Analog Devices, Inc., Wilmington, MA (US)

(21) Appl. No.: 18/730,912

(22) PCT Filed: Jan. 24, 2023
(86) PCT No.: PCT/US2023/011465

§ 371 Date: Jul. 22, 2024

Related U.S. Application Data
(60) Provisional application No. 63/303,013, filed on Jan. 25, 2022.

(51) Int. Cl. H01L 25/16; B81B 7/00; H01L 23/538

(52) U.S. Cl. CPC H01L 25/16; B81B 7/008; H01L 23/5385

(57) ABSTRACT

Compact packages including microelectromechanical system (MEMS) devices and multiple application specific integrated circuits (ASICs) are described. These packages are sufficiently small to be applicable to contexts in which space requirements are particularly strict, such as in consumer electronics. These packages involve vertical die stacks. A first ASIC may be positioned on one side of the die stack and another ASIC may be positioned on the other side of the die stack. A die including a MEMS device (e.g., an accelerometer, gyroscope, switch, resonator, optical device) is positioned between the ASICs. Optionally, an interposer serving as cap substrate for the MEMS device is also positioned between the ASICs. In one example, a package of the types described herein has an extension of 2 mm×2 mm in the planar axes and less than 500-800 μm in height.

### CROSS-REFERENCE TO RELATED APPLICATION

This application claims the benefit under 35 U.S.C. § 119(e) of U.S. Application Ser. No. 63/303,013, filed Jan. 25, 2022, under Attorney Docket No. G0766.70349US00 and entitled “HETEROGENEOUS INTEGRATION OF MEMS SENSORS AND MULTIPLE CIRCUIT CHIPS,” which is hereby incorporated herein by reference in its entirety.

### FIELD OF THE DISCLOSURE

The technology described in the present application relates to microelectromechanical system (MEMS) devices and related packages.

### BACKGROUND

Microelectromechanical system (MEMS) devices include inertial sensors that measure and report motion, forces, angular rates, and/or other quantities. Examples of MEMS devices include gyroscopes, accelerometers, switches and resonators, among others. Electronic circuits are used to drive motion and/or sense motion of the MEMS device.

### SUMMARY OF THE DISCLOSURE

Some embodiments relate to compact packages including microelectromechanical system (MEMS) devices and multiple application specific integrated circuits (ASICs). These packages are sufficiently small to be applicable to contexts in which space requirements are particularly strict, such as in consumer electronics. These packages involve vertical die stacks. A first ASIC may be positioned on one side of the die stack and another ASIC may be positioned on the other side of the die stack. A die including a MEMS device (e.g., an accelerometer, gyroscope, switch, resonator, optical device) is positioned between the ASICs. Optionally, an interposer serving as a cap substrate for the MEMS device is also positioned between the ASICs. In one example, a package of the types described herein has an extension of 2 mm×2 mm in the planar axes and less than 500-800 μm in height.

Some embodiments relate to a microelectromechanical system (MEMS) package, comprising: a substrate having a top surface; and a die stack bonded to the substrate and extending in a first direction perpendicular to the top surface of the substrate, the die stack comprising: a first application specific integrated circuit (ASIC); a die, comprising a MEMS device, in communication with the first ASIC; and a second ASIC in communication with the first ASIC, wherein the first ASIC, the die and the second ASIC are stacked with one another in the first direction.

In some embodiments, the die is disposed between the first ASIC and the second ASIC with respect to the first direction.

In some embodiments, the die stack comprises a plurality of thru silicon vias (TSVs) electrically coupling the first ASIC with the second ASIC.

In some embodiments, the MEMS package further comprises first and second bonds offset from each other in a second direction perpendicular to the first direction, the first and second bonds bonding the die stack to the top surface of the substrate, wherein the second ASIC is disposed between the first and second bonds with respect to the second direction.

In some embodiments, the first bond is thicker than the second ASIC with respect to the first direction.

In some embodiments, the first bond is at least 150 μm in thickness with respect to the first direction.

In some embodiments, the first ASIC comprises sense circuitry configured to sense motion of the MEMS device.

In some embodiments, the second ASIC comprises digital circuitry coupled to the sense circuitry.

In some embodiments, the MEMS device is positioned closer to the first ASIC than to the second ASIC with respect to the first direction.

In some embodiments, the die stack further comprises an interposer disposed between the die and the second ASIC with respect to the first direction, the interposer defining a cavity to which the MEMS device is aligned.

In some embodiments, the die stack comprises a plurality of stress isolation platforms, at least one of the plurality of stress isolation platforms defining a portion of the die stack that is flexibly coupled to a remainder of the die stack by a plurality of stress isolation suspensions.

In some embodiments, the first and second ASICs are disposed on opposite ends of the die stack.

Some embodiments relate to a microelectromechanical system (MEMS) package, comprising: a substrate having a top surface; a first application specific integrated circuit (ASIC), having circuit features sized at a first fabrication process node; a die, comprising a MEMS device, coupled to the first ASIC; an interposer defining a cavity to which the MEMS device is aligned, wherein the die is disposed between the first ASIC and the interposer with respect to a first direction perpendicular to the top surface of the substrate, wherein the interposer is bonded to the top surface of the substrate by a plurality of bonds; and a second ASIC, having circuit features sized at a second fabrication process node different from the first fabrication process node, the second ASIC being disposed between the interposer and the substrate with respect to the first direction.

In some embodiments, the second ASIC has a lateral extension that is less than a lateral extension of the interposer with respect to a second direction perpendicular to the first direction.

In some embodiments, the second ASIC is disposed between first and second bonds of the plurality of bonds with respect to the second direction.

In some embodiments, the interposer comprises a plurality of stress isolation platforms, at least one of the plurality of stress isolation platforms defining a portion of the interposer that is flexibly coupled to a remainder of the interposer by a plurality of stress isolation suspensions.

In some embodiments, the first ASIC comprises sense circuitry configured to sense motion of the MEMS device, and the second ASIC comprises digital circuitry coupled to the sense circuitry.

Some embodiments relate to a microelectromechanical system (MEMS) package, comprising: a substrate having a top surface; a die stack bonded to the substrate and extending in a first direction perpendicular to the top surface of the substrate, the die stack comprising: a first application specific integrated circuit (ASIC); a die, comprising a MEMS device, coupled to the first ASIC; and a second ASIC, coupled to the die, wherein the die is disposed between the first ASIC and the second ASIC with respect to the first direction; and first and second bonds offset from each other in a second direction perpendicular to the first direction, the first and second bonds bonding the die stack to the top surface of the substrate, wherein the second ASIC is disposed between the first and second bonds with respect to the second direction.

In some embodiments, the die stack comprises a plurality of stress isolation platforms, at least one of the plurality of stress isolation platforms defining a portion of the die stack that is flexibly coupled to a remainder of the die stack by a plurality of stress isolation suspensions.

In some embodiments, the first ASIC comprises sense circuitry configured to sense motion of the MEMS device, and the second ASIC comprising digital circuitry coupled to the sense circuitry.

### BRIEF DESCRIPTION OF THE DRAWINGS

The accompanying drawings are not intended to be drawn to scale. In the drawings, each identical or nearly identical component that is illustrated in various figures may be represented by a reference numeral or character. For purposes of clarity, not every component may be labeled in every drawing. In the drawings:

FIG. 1 is a block diagram illustrating a microelectromechanical system (MEMS) die coupled to a pair of application specific integrated circuits (ASICs), in accordance with some embodiments of the present application.

FIG. 2A is a schematic side view illustrating a die stack including a first ASIC, a MEMS die and a second ASIC, in accordance with some embodiments of the present application.

FIG. 2B is a schematic side view illustrating a die stack including a first ASIC, a MEMS die, an interposer and a second ASIC, in accordance with some embodiments of the present application.

FIG. 3A is a schematic cross-sectional view illustrating a package including a first ASIC, a MEMS die and a second ASIC, in accordance with some embodiments of the present application.

FIG. 3B is a schematic cross-sectional view illustrating a portion of the die stack of FIG. 3A in additional detail, in accordance with some embodiments of the present application.

FIG. 3C is a schematic top view of the MEMS die of FIG. 3A, in accordance with some embodiments of the present application.

FIG. 4A is a schematic cross-sectional view illustrating a package including a first ASIC, a MEMS die, an interposer and a second ASIC, in accordance with some embodiments of the present application.

FIG. 4B is a schematic top view of the interposer of FIG. 4A, in accordance with some embodiments of the present application.

FIG. 5 is a schematic top view illustrating a stress isolation platform of the die stack of FIG. 3A, in accordance with some embodiments of the present application.

### DETAILED DESCRIPTION

### I. Overview

Aspects of the present application relate to compact packages including microelectromechanical system (MEMS) devices and multiple application specific integrated circuits (ASICs). Compactness is achieved using die stacks. A first ASIC (e.g., including analog circuitry) may be positioned on the top side of the die stack and another ASIC (e.g., including digital circuitry) may be positioned on the bottom side of the die stack. A die including a MEMS device (e.g., an accelerometer, gyroscope, switch, resonator, optical device) is positioned between the ASICs. For the reasons discussed below, these packages can be made sufficiently small for use in contexts in which space requirements are particularly tight, including in consumer electronics. In one example, a package of the types described herein has an extension equal to or less than 2 mm×2 mm in the plane of the package and less than 500-800 μm in height (excluding the underlying substrate).

Applicant has appreciated that separating the functionality of the processing electronics to multiple ASICs presents certain benefits over implementations in which all the processing electronics are on a common ASIC. Placing (at least some of) the analog circuits in one ASIC and (at least some of) the digital circuits in another ASIC allows designers to optimize those circuits independently of one another. For example, this approach allows designers to select a fabrication process node that is more suitable for use with analog circuitry and, separately, to select a fabrication process node that is more suitable for use with digital circuitry. A larger process node (e.g., 0.18 μm) may be more suitable for the analog ASIC, where high voltage levels are often required to drive and sense motion of a MEMS device. A smaller process node (e.g., 22 nm) may be more suitable for the digital ASIC, where computational speed and low power consumption are of greater importance.

Applicant has appreciated, however, that co-packaging the additional ASIC with the MEMS die leads to a larger form factor. Larger form factors limit the applicability of such devices in items such as consumer electronics. Aspects of the present application relate to packages arranged in die stacks in which dies are stacked on top of one another in the vertical direction. The vertical nature of this configuration limits the lateral extension of the package. Compactness in the vertical direction may be achieved by reducing the lateral extension of the bottom ASIC, relative to the die that covers it, so that a pocket in which the bottom ASIC can be embedded is formed between adjacent bonds (the bonds that connect the die stack to the underlying substrate). In this way, the thickness of bottom ASIC does not contribute to the overall thickness of the package, or at most, its contribution is only partial.

The die stacks described herein may rely on thru silicon vias (TSVs) to perform signal routing across the die stack in the vertical direction. A TSV is a type of electrical interconnect that allows vertically-stacked dies to electrically communicate with each other. For example, in a hypothetical die stack including dies X, Y and Z where X is on top of Y and Y is on top of Z, TSVs passing through middle die Y can place dies X and Z in communication with each other. TSVs can be formed by etching vertical trenches through the thickness of a chip in accordance with a predefined pattern, and by filling the trenches with conductive material. According to one aspect, the die stacks described herein are arranged so that TSVs are passed through a passive chip (a chip that lacks transistors), as opposed to being passed through one of the ASICs (which may be viewed as active chips in that they include transistors). For example, the TSVs may be passed either through the die hosting the MEMS devices (the MEMS die) or through the interposer serving as cap substrate for the MEMS device, where such an interposer is included. In either configuration, the result is that the MEMS device is sandwiched between the ASICs. Applicant has appreciated that passing the TSVs through a passive chip reduces disruption to the circuitry of a die stack that would otherwise occur if one of the ASICs were placed in the middle of the stack. First, passing TSVs through an ASIC would limit the density of the circuits of the ASICs because of the space requirements associated with TSVs. Second, it may result in stress, caused by the etching step (required to form the via), bleeding into the circuits. Stress in the circuits can reduce their performance and lifetime.

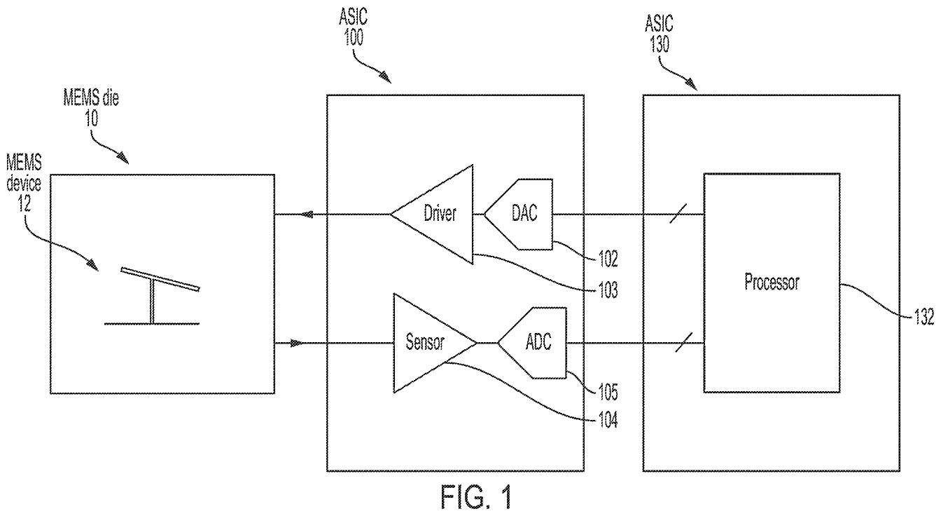

Unfortunately, passing the TSVs either through the MEMS die or the interposer can increase complexity in terms of signal routing. From a signal path standpoint, the analog ASIC may be viewed as being functionally in the middle between the MEMS die and the digital ASIC. In fact, as can be appreciated below in connection with FIG. 1, the analog ASIC receives, adapts and transmits to the digital ASIC signals generated by the MEMS die, and receives, adapts and transmits to the MEMS die signals generated by the digital ASIC. Accordingly, placing the analog ASIC to be physically in the middle of the die stack would result in fewer and/or shorter interconnects relative to placing the MEMS die or the interposer to be physically in the middle of the die stack. On balance, Applicant has appreciated that the positive effects of placing the MEMS die or the interposer to be physically in the middle of the die stack (avoiding TSVs through the ASICs) outweighs its negative effects (added complexity in terms of signal routing).

Accordingly, some embodiments relate to MEMS packages having a substrate having a top surface and a die stack bonded to the substrate. The die stack extends in a first direction perpendicular to the top surface of the substrate. The die stack includes a first ASIC having circuit features sized at a first fabrication process node, a MEMS die coupled to the first ASIC, and a second ASIC coupled to the die. The second ASIC has circuit features sized at a second fabrication process node different from the first fabrication process node. The MEMS die is disposed between the first ASIC and the second ASIC with respect to the first direction. The first ASIC may include analog circuitry and the second ASIC may include digital circuitry. Optionally, an interposer serving as a cap substrate for the MEMS device is further positioned between the ASICs. TSVs passing through the MEMS die (and/or the interposer) enable signal routing between the ASICs. First and second bonds, offset from each other in a second direction perpendicular to the first direction, may bond the die stack to the top surface of the substrate. The bottom ASIC may be disposed between the first and second bonds with respect to the second direction.

Applicant has further appreciated that package stress—resulting from the integration of materials having different coefficients of thermal expansion—may negatively affect the performance and lifetime of the MEMS die and the ASICs. Applicant has developed techniques to achieve stress isolation of the die stacks. In some aspects, stress isolation features are included in a die stack that reduce or eliminate the propagation of stresses from the packaging to the MEMS dies and the ASICs. Thus, the packaged devices may effectively be isolated from external stresses. As a result, sensitive electronics and/or mechanical components of the package may be protected, and the negative effects of undesired stresses on the device operation may be mitigated.

### II. Die Stacks

FIG. 1 is a block diagram illustrating a MEMS die 10 coupled to ASICs 100 and 130, in accordance with some embodiments of the present application. MEMS die 10 is in communication with ASIC 100, and ASIC 130 is also in communication with ASIC 100. MEMS die 10 includes one or MEMS devices 12, examples of which include MEMS accelerometers, MEMS gyroscopes, MEMS switches, MEMS resonators and MEMS optical devices, among others. MEMS device 12 may include a proof mass connected to the substate of die 10 via an anchor, for example. The proof mass may be free to move (e.g., to tilt or translate) in response to external forces (e.g., acceleration) and/or in response to a drive signal.

ASICs 100 and 130 are configured to generate signals for driving MEMS device(s) 12 and/or to process signals received from MEMS device(s) 12. In some embodiments, the analog circuitry is disposed on one ASIC and the digital processing circuitry is disposed on the other ASIC. ASIC 100 includes digital-to-analog converter (DAC) 102, driver 103, sensor 104 and analog-to-digital converter (ADC) 105. ASIC 130 includes digital processor 132. DAC 102 is configured to convert digital signals generated by processor 132 into the analog domain for use by driver 103. Driver 103 uses the output of DAC 102 to produce analog signals for driving MEMS device(s) 12. For example, in those embodiments in which MEMS device 12 includes a gyroscope or a resonator, driver 103 may produce periodic signals. Alternatively, in those embodiments in which MEMS device 12 includes a switch, driver 103 may produce a signal intended to route signals in the desired direction (e.g., by selecting a particular input and/or a particular output of the switch). The voltage level to be produced by driver 103 depends on the nature of the MEMS device (e.g., the size and the weight of the proof mass, and the separation between the proof mass and the underlying substrate of MEMS die 10), and it could exceed 1 V or 10 V in some embodiments. Sensor 104 senses signals produced by MEMS device (12) in response to an external input. For example, in those embodiments in which MEMS device 12 includes an accelerometer, sensor 104 is configured to quantify the acceleration experienced by the MEMS device. In those embodiments in which MEMS device 12 includes a gyroscope, sensor 104 is configured to quantify the angular motion experienced by the MEMS device. Processor 132 may be programmed to run digital algorithms designed to store, organize, interpret and transmit the data obtained from MEMS device(s) 12.

Separating the analog circuitry from the digital circuitry in distinct ASICs enables the analog circuitry and digital circuitry to be separately designed and manufactured. For example, this approach allows designers to select a fabrication process node that is suitable for analog circuitry and, separately, to select a fabrication process node that is suitable for digital circuitry. Having distinct fabrication process nodes results in the circuit features of the ASICs having different sizes. For example, the fabrication process node may affect the geometry of the transistors, including the channel length of a transistor, where the channel supports passage of electric current through the drain and source. Transistors with shorter channels tend to be faster and more energy efficient than transistors with longer channels. However, transistors with longer channels can support higher voltage levels than transistors with shorter channels. For example, some of the smaller fabrication process nodes do not support voltage levels above 0.9V. Accordingly, larger fabrication process nodes may be more suitable for DAC 102, driver 103, sensor 104 and DAC 105, the operation of which can involve voltage levels in excess of 1 V or 10V, depending upon the nature of the MEMS device. By contrast, smaller fabrication process nodes may be more suitable for processor 132, where computational speed and low power consumption are of greater importance.

In some embodiments, the fabrication process node used in the fabrication of ASIC 100 is larger than the fabrication process node used in the fabrication of ASIC 130. For example, ASIC 100 may be fabricated using a 0.18 μm process node, a 0.15 μm process node or a 0.13 μm process node, and ASIC 130 may be fabricated using a 32 nm process node, a 22 nm process node or a 14 nm process node, among other possible options.

The arrangement of FIG. 1 presents a challenge. Packaging a MEMS die 10 together with two ASICs requires more space than packaging a MEMS die with a single ASIC. For some applications (e.g., consumer electronics), increasing the size of the package may be unacceptable.

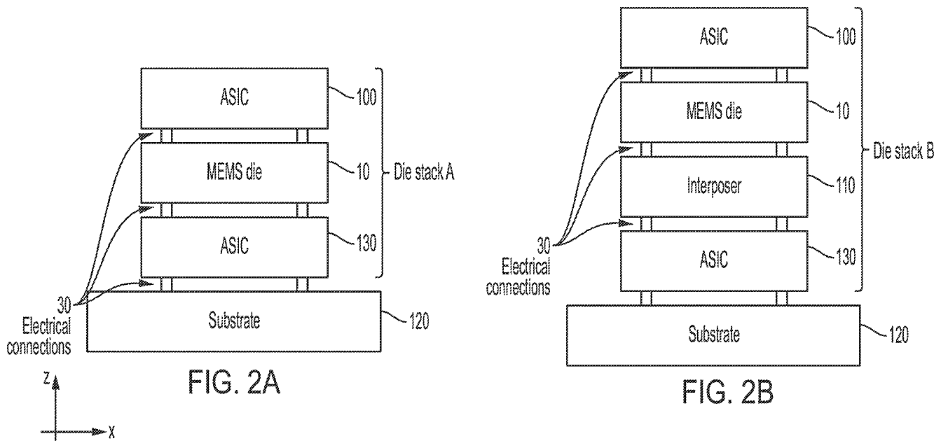

Aspects of the present application relate to compact packages that are suitable for use in applications having tight space requirements. The packages described herein involve die stacks, examples of which are illustrated in FIGS. 2A-2B, in accordance with some embodiments. Die stack A, illustrated in the schematic side view of FIG. 2A, includes ASIC 100, MEMS die 10, and ASIC 130. From a functional standpoint, ASICs 100 and 130 and MEMS die 10 may operate in the manner discussed in connection with FIG. 1. Die stack A is arranged so that the chips are stacked on top of one another along the vertical direction (parallel to the z-axis), with MEMS die 10 being positioned between ASIC 100 and ASIC 130. In this illustration, ASIC 100 is disposed on top of MEMS die 10 and MEMS die 10 is disposed on top of ASIC 130. However, the position of ASIC 100 and ASIC 130 may be swapped with one another, with MEMS die 10 remaining in the middle. Die stack A is disposed on a substrate 120, which could be a printed circuit board or a laminate substrate, among other options. Electrical connections 30 support signal routing between the chips. Examples of electrical connections 30 include solder bumps, solder balls, and copper pillars, among others. It should be noted that the electrical connections coupling ASIC 100 to MEMS die 10 may differ in nature relative to the electrical connections coupling ASIC 130 to MEMS die 10 and/or relative to the electrical connections coupling ASIC 130 to substrate 120. Electrical connections 30 may couple to thru silicon vias (not shown in FIG. 2A) passing through MEMS die 10. Die stack B, illustrated in the schematic side view of FIG. 2B, is similar to die stack A, but it further includes an interposer 110 disposed between MEMS die 10 and ASIC 130. In the example of FIG. 2A, the hermetically sealed cavities in which the MEMS devices are disposed are defined entirely in the MEMS die 10. By contrast, in the example of FIG. 2B, the hermetically sealed cavities are defined in part in interposer 110. In that respect, interposer 110 may be viewed as a cap substrate for MEMS device 12. As in FIG. 2A, electrical interconnects 30 provide signal routing across the die stack, and couple to thru silicon vias (not shown in FIG. 2B) passing through interposer 110 and MEMS die 10.

In some embodiments, to further limit the vertical extension of the package, the die stacks of FIGS. 2A-2B do not include any additional dies (whether active or passive) beyond those illustrated. Thus, in those embodiments, ASIC 100 is at the top end of the stack and ASIC 130 is at the bottom end of the stack. However, not all embodiments are limited in this respect.

Applicant has appreciated that the die stacks of FIGS. 2A-2B present several advantages over other implementations. First, because the chips are stacked in the vertical direction, the planar extension of the package (in the plane defined by the x-axis and the y-axis) is limited.

Second, placing the ASICs at opposite sides of the die stacks allows the thru silicon vias to pass through a passive chip (either through MEMS die 10 or interposer 110). MEMS die 10 and interposer 110 may be considered passive chips in that they may lack transistors. On the other hand, the ASICs are considered active chips in that they do include transistors. Applicant has appreciated that passing the thru silicon vias through passive chips is advantageous over passing thru silicon vias through active chips because it reduces disruption to the circuitry of the die stacks. This is because passing thru silicon vias through active chips may limit the density of the circuits of the ASICs, or worse, may result in stress caused by the etching step (required to form the via) bleeding into the circuits. Stress in the circuits can reduce their performance and lifetime. From a signal path standpoint, as can be appreciated from FIG. 1, ASIC 100 may be viewed as being functionally in the middle between MEMS die 10 and ASIC 130 (ASIC 100 receives, adapts and transmits to ASIC 130 signals generated by MEMS die 10, and receives, adapts and transmits to MEMS die 10 signals generated by ASIC 130). Accordingly, placing ASIC 100 to be physically in the middle of the die stack would result in fewer and/or shorter interconnects relative to placing MEMS die 10 or the interposer 110 to be physically in the middle of the die stack. On balance, Applicant has appreciated that the positive effects of placing MEMS die 10 or interposer 110 to be in the middle of the die stack (avoiding TSVs through the ASICs) outweighs its negative effects (added complexity in terms of signal routing).

Third, as discussed in detail further below, these arrangements allow the bottom chip of the stack (ASIC 130 in the examples of FIGS. 2A-2B) to be disposed in the pocket formed between the bonds bonding the die stack to substrate 120. As a result, the thickness of the bottom chip does not contribute (or contributes only partially) to the overall thickness of the package in the vertical direction. This limits the vertical extension of the package.

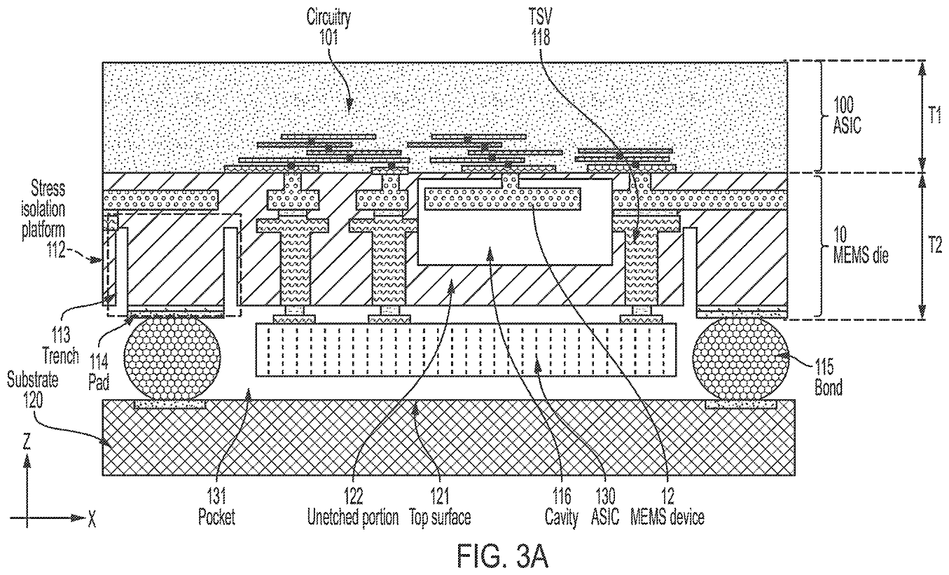

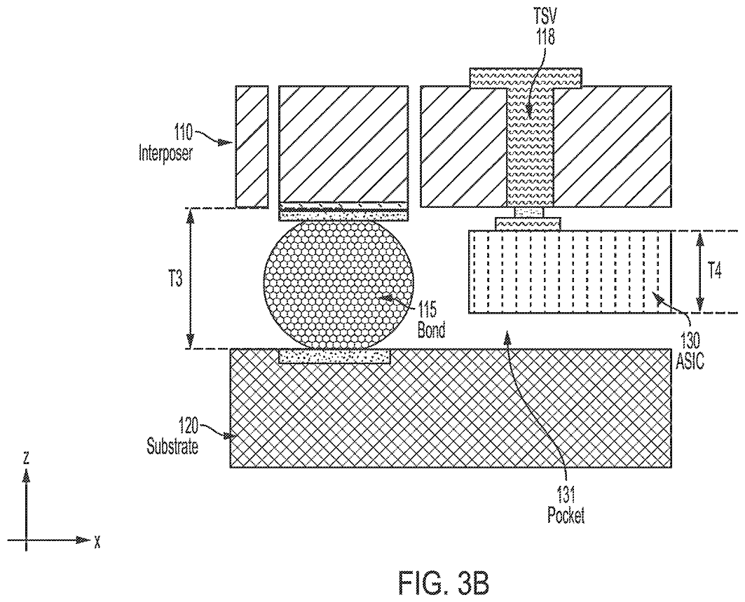

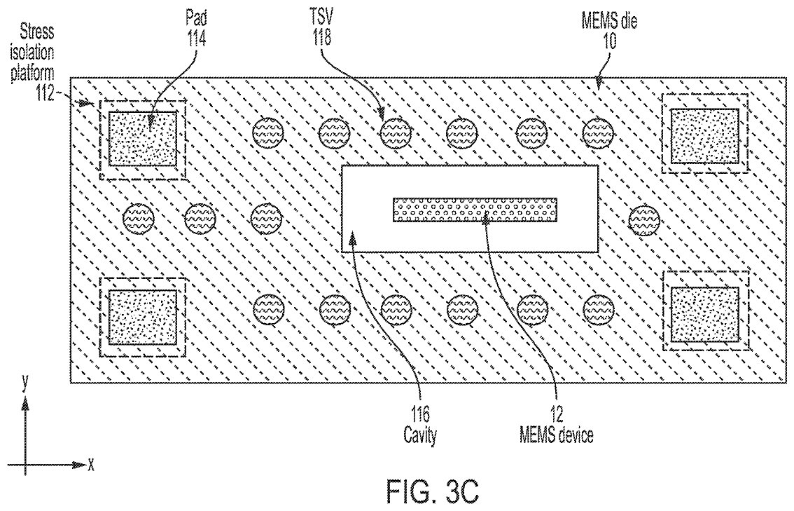

FIG. 3A is a schematic cross sectional view illustrating an implementation of die stack A, in accordance with some embodiments of the present application. In this example, ASIC 100 sits on top of the die stack and ASIC 130 sits on the bottom, with MEMS die 10 being disposed in the middle. Circuitry 101, which may include DAC 102, driver 103, sensor 104 and ADC 105, is patterned in ASIC 100. MEMS die 10 defines a cavity 116 in which MEMS device 12 is disposed. The cavity allows the MEMS device to move freely. Unetched portion 122 of die 10 mechanically supports the cavity. MEMS die 10 is arranged so that MEMS device 12 is disposed on the top part of the die. As a result, MEMS device 12 is closer to ASIC 100 than it is to ASIC 130. This arrangement limits the length of the electrical paths coupling the MEMS device to circuitry 101, thus limiting signal loss. Thru silicon vias (TSVs) 118 pass through MEMS die 10 and enable signal routing between ASIC 100 and ASIC 130.

The bottom surface of MEMS die 10 is bonded to top surface 121 of substrate 120 by bonds 115. Bonds 115 may include solder bumps, solder balls, or a ball grid array, copper pillars, among others. Metal pads 114 are formed on the bottom surface of die 10 and electrically couple to bonds 115. ASIC 130 is disposed in pocket 131, formed between a pair of adjacent bonds 115 with respect to the x-axis. In the example of FIG. 3A, ASIC 130 is suspended above substrate 120, although not all embodiments are limited in this respect. The lateral extension of ASIC 130 with respect to the x-axis may be less than the lateral extension of die 10, leading to the formation of a pocket in which ASIC 130 can be disposed.

The thickness of ASIC 100 (T1) may be less than 300 μm or 350 μm. In some embodiments, T1 is between 200 μm and 250 μm, between 250 μm and 300 μm, between 300 μm and 350 μm or between 200 μm and 350 μm. The thickness of die 10 (T2) may be less than 200 μm or 250 μm. In some embodiments, T2 is between 150 μm and 200 μm, between 200 μm and 250 μm, or between 150 μm and 150 μm.

Referring to FIG. 3B, the thickness of bond 115 (T3) may be greater than the thickness of ASIC 130 (T4). For example, T3 may be greater than 150 μm or 200 μm, and T4 may be less than 100 μm or 200 μm. In some embodiments, T3 is between 150 μm and 200 μm, between 200 μm and 250 μm or between 150 μm and 250 μm. In some embodiments, T4 is between 50 μm and 100 μm, between 100 μm and 150 μm, between 150 μm and 200 μm or between 50 μm and 200 μm. Being thinner than bonds 115 allows ASIC 130 to be embedded in the space underneath die 10 and between bonds 115 (pocket 131). As a result, the thickness of ASIC 130 does not contribute (or contributes only partially) to the overall thickness of the package, thus limiting its vertical extension.

FIG. 3C is a schematic top view of MEMS die 10, in accordance with some embodiments of the present application. This figure illustrates the relative placement of TSVs 118, pads 114, stress isolation platforms 112, cavity 116 and MEMS device 12. It should be noted that MEMS die 10 may include other components not illustrated in FIG. 3C. MEMS device 12 is bounded by the walls of cavity 116. TSVs 118 are positioned not to interfere with cavity 116 or pads 114. Stress isolation platforms 112 are positioned in correspondence with pads 114, as discussed in detail further below.

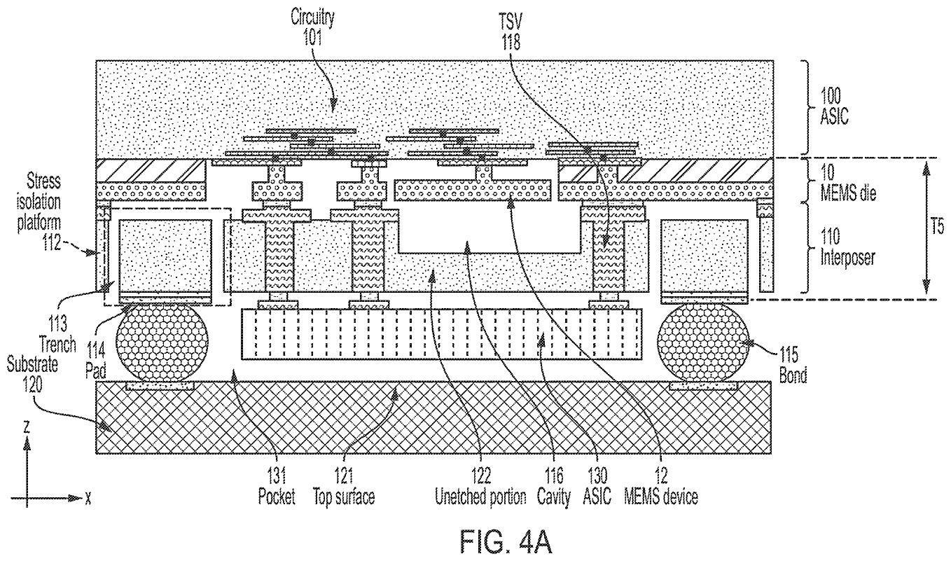

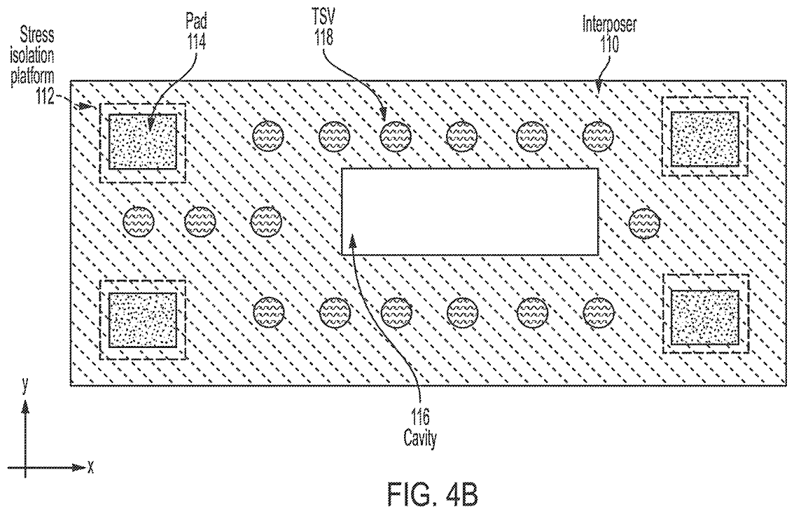

FIG. 4A is a schematic cross sectional view illustrating an implementation of die stack B, in accordance with some embodiments of the present application. In this example, ASIC 100 is on top of the die stack and ASIC 130 is on the bottom, with MEMS die 10 and interposer 110 being disposed in the middle. In this die stack, part of the cavity (116) in which MEMS device 12 is disposed is formed in interposer 110. Cavity 116, which is mechanically supported by the unetched portion 122 of interposer 110, is aligned with MEMS device 12. Accordingly, interposer 110 may serve as a cap substrate for MEMS die 10. MEMS die 10 and interposer 110 are positioned so that MEMS device 12 is disposed near ASIC 100. As a result, MEMS device 12 is closer to ASIC 100 than it is to ASIC 130. This arrangement limits the length of the electrical paths coupling the MEMS device to circuitry 101, thus limiting signal loss. Thru silicon vias (TSVs) 118 pass through interposer 110 and enable signal routing between ASIC 100 and ASIC 130.

In this die stack, the bottom surface of interposer 110 is bonded to substrate 120 by bonds 115. Metal pads 114 are formed on the bottom surface of interposer 110 and electrically couple to bonds 115. As in the die stack of FIG. 3A, ASIC 130 is disposed in the pocket 131, formed between a pair of adjacent bonds 115 with respect to the x-axis. The lateral extension of ASIC 130 with respect to the x-axis may be less than the lateral extension of interposer 110, leading to the formation of a pocket in which ASIC 130 can be disposed without necessarily increasing the overall thickness of the package.

In the die stack of FIG. 4A, the thickness of ASICs 100 and 130 may be in the same ranges as the corresponding thicknesses discussed above in connection with FIG. 3A. The sum of the thicknesses of MEMS die 10 and interposer 110 (T5) may be less than 250 μm or 300 μm. In some embodiments, T5 is between 100 μm and 300 μm, between 150 μm and 250 μm, between 200 μm and 250 μm or between 250 μm and 300 μm.

FIG. 4B is a schematic top view of interposer 110, in accordance with some embodiments of the present application. This figure illustrates the relative placement of TSVs 118, pads 114, stress isolation platforms 112 and cavity 116. MEMS device 12 is not illustrated in FIG. 4B because it is part of MEMS die 10, not of interposer 110. It should be noted that interposer 110 may include other components not illustrated in FIG. 4B. As in the top view of FIG. 3C, TSVs 118 are positioned not to interfere with cavity 116 or pads 114. Stress isolation platforms 112 are positioned in correspondence with pads 114, as discussed in detail further below.

### III. Stress Isolation Platforms

Some aspects relate to stress isolation of die stacks. Applicant has appreciated that including stress isolation features in a die stack may reduce or eliminate the propagation of stresses from the packaging to the MEMS dies and the ASICs. Thus, the packaged devices may effectively be isolated from external stresses. As a result, sensitive electronics and/or mechanical components of the package may be protected, and the negative effects of undesired stresses on the device operation may be mitigated.

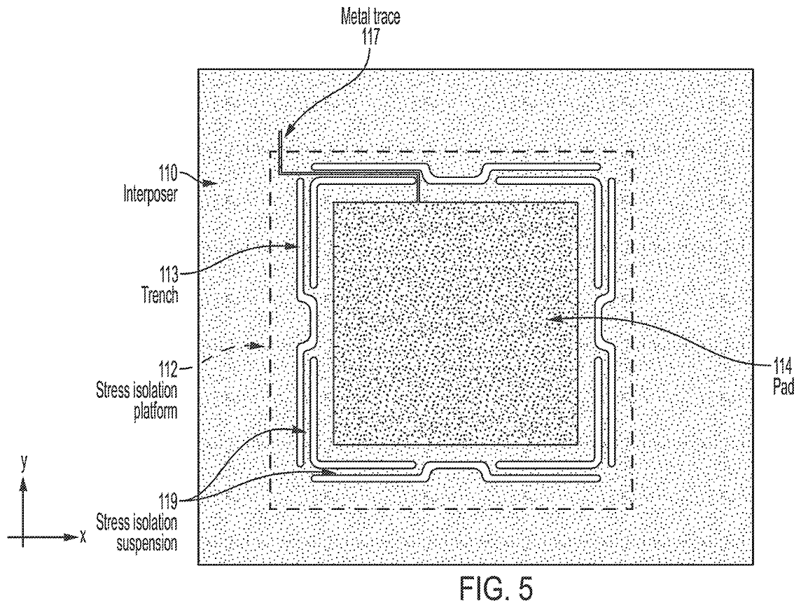

As further illustrated in FIGS. 3A and 4, die stacks A and B may include stress isolation platforms 112, configured to mechanically isolate MEMS die 10 and ASICs 100 and 130 from stress propagating from substrate 120. FIG. 5 illustrates a top view of a stress isolation platform 112, formed on interposer 110. Stress isolation platform 112 may be a dual-purpose platform providing both mechanical stress isolation and electrical connectivity between substrate 120 and interposer 110. Stress isolation platforms 112 serve as coupling points for coupling interposer 110 to substrate 120. Thus, bonds 115 connect to regions of interposer 100 in which stress isolations platforms are present. Stress isolation platform 112 may include a plurality of stress isolation suspensions 119 defined at least in part by a plurality of stress isolation trenches 113 (also shown in FIG. 4A) that are etched through the interposer. The remaining stress isolation suspensions 119 flexibly couple the stress isolation platforms 112 to the remaining part of the interposer 110. Thus, the stress isolation platforms 112 and the remaining part of the interposer 110 are free to move relative to each other, being mechanically independent of each other. The stress isolation platforms 112 also provide electrical interconnectivity between substrate 120 and interposer 110. Metal pad 114 may be provided on a stress isolation platform 112, and one or more metal traces 117 may be routed from the stress isolation platform 112 over to electrical connection points on the device. In embodiments in which the die stack lacks interposer 110, similar stress isolation platforms may be implemented directly on MEMS die 10, as shown in FIG. 3A.

### IV. Conclusion

Aspects of the present application may provide one or more benefits, some of which have been previously described. Now described are some non-limiting examples of such benefits. It should be appreciated that not all aspects and embodiments necessarily provide all of the benefits now described. Further, it should be appreciated that aspects of the present application may provide additional benefits to those now described.

Aspects of the present application provide MEMS packages that are small notwithstanding that the functionality of the processing electronics is divided into multiple ASICs. Compactness in the lateral direction results from the vertical configuration of the package. Compactness in the vertical direction is achieved by embedding the bottom ASIC in the pocket formed between adjacent bonds. In this way, the thickness of the bottom die does not contribute to the overall thickness of the package, or contributes only partially. In one example, a package of the types described herein has an extension equal to or less than 2 mm×2 mm in the plane of the package and less than 500-800 μm in height.

The die stacks described herein rely on TSVs to perform signal routing across the die stack. Passage of TSVs near a circuit may disrupt its performance and lifetime. Aspects of the present application limits disruption to the circuits by sandwiching the MEMS device between the ASICs. In this way, TSVs can be passed through a chip that does not include active electronics.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

As used herein, reference to a numerical value being between two endpoints should be understood to encompass the situation in which the numerical value can assume either of the endpoints. For example, stating that a characteristic has a value between A and B, or between approximately A and B, should be understood to mean that the indicated range is inclusive of the endpoints A and B unless otherwise noted.

1. A microelectromechanical system (MEMS) package, comprising:
a substrate having a top surface; and
a die stack bonded to the substrate and extending in a first direction perpendicular to the top surface of the substrate, the die stack comprising:
a first application specific integrated circuit (ASIC);
a die, comprising a MEMS device, in communication with the first ASIC; and
a second ASIC in communication with the first ASIC, wherein the first ASIC, the die and the second ASIC are stacked with one another in the first direction.

2. The MEMS package of claim 1, wherein the die is disposed between the first ASIC and the second ASIC with respect to the first direction.

3. The MEMS package of claim 2, wherein the die stack comprises a plurality of thru silicon vias (TSVs) electrically coupling the first ASIC with the second ASIC.

4. The MEMS package of claim 2, further comprising first and second bonds offset from each other in a second direction perpendicular to the first direction, the first and second bonds bonding the die stack to the top surface of the substrate, wherein the second ASIC is disposed between the first and second bonds with respect to the second direction.

5. The MEMS package of claim 4, wherein the first bond is thicker than the second ASIC with respect to the first direction.

6. The MEMS package of claim 5, wherein the first bond is at least 150 μm in thickness with respect to the first direction.

7. The MEMS package of claim 2, wherein the first ASIC comprises sense circuitry configured to sense motion of the MEMS device.

8. The MEMS package of claim 7, wherein the second ASIC comprises digital circuitry coupled to the sense circuitry.

9. The MEMS package of claim 8, wherein the MEMS device is positioned closer to the first ASIC than to the second ASIC with respect to the first direction.

10. The MEMS package of claim 2, wherein the die stack further comprises an interposer disposed between the die and the second ASIC with respect to the first direction, the interposer defining a cavity to which the MEMS device is aligned.

11. The MEMS package of claim 2, wherein the first and second ASICs are disposed on opposite ends of the die stack.

12. The MEMS package of claim 1, wherein the die stack comprises a plurality of stress isolation platforms, at least one of the plurality of stress isolation platforms defining a portion of the die stack that is flexibly coupled to a remainder of the die stack by a plurality of stress isolation suspensions.

13. A microelectromechanical system (MEMS) package, comprising:
a substrate having a top surface;
a first application specific integrated circuit (ASIC), having circuit features sized at a first fabrication process node;
a die, comprising a MEMS device, coupled to the first ASIC;
an interposer defining a cavity to which the MEMS device is aligned, wherein the die is disposed between the first ASIC and the interposer with respect to a first direction perpendicular to the top surface of the substrate, wherein the interposer is bonded to the top surface of the substrate by a plurality of bonds; and
a second ASIC, having circuit features sized at a second fabrication process node different from the first fabrication process node, the second ASIC being disposed between the interposer and the substrate with respect to the first direction.

14. The MEMS package of claim 13, wherein the second ASIC has a lateral extension that is less than a lateral extension of the interposer with respect to a second direction perpendicular to the first direction.

15. The MEMS package of claim 14, wherein the second ASIC is disposed between first and second bonds of the plurality of bonds with respect to the second direction.

16. The MEMS package of claim 13, wherein the interposer comprises a plurality of stress isolation platforms, at least one of the plurality of stress isolation platforms defining a portion of the interposer that is flexibly coupled to a remainder of the interposer by a plurality of stress isolation suspensions.

17. The MEMS package of claim 13, wherein the first ASIC comprises sense circuitry configured to sense motion of the MEMS device, and the second ASIC comprises digital circuitry coupled to the sense circuitry.

18. A microelectromechanical system (MEMS) package, comprising:
a substrate having a top surface;
a die stack bonded to the substrate and extending in a first direction perpendicular to the top surface of the substrate, the die stack comprising:
a first application specific integrated circuit (ASIC);
a die, comprising a MEMS device, coupled to the first ASIC; and
a second ASIC, coupled to the die, wherein the die is disposed between the first ASIC and the second ASIC with respect to the first direction; and
first and second bonds offset from each other in a second direction perpendicular to the first direction, the first and second bonds bonding the die stack to the top surface of the substrate, wherein the second ASIC is disposed between the first and second bonds with respect to the second direction.

19. The MEMS package of claim 18, wherein the die stack comprises a plurality of stress isolation platforms, at least one of the plurality of stress isolation platforms defining a portion of the die stack that is flexibly coupled to a remainder of the die stack by a plurality of stress isolation suspensions.

20. The MEMS package of claim 18, wherein, the first ASIC comprises sense circuitry configured to sense motion of the MEMS device, and the second ASIC comprising digital circuitry coupled to the sense circuitry.
